(19) United States
(12) Patent Application Publication
(10) Pub. No.: US 2012/0314344 A1
(43) Pub. Date: Dec. 13, 2012

(54) HAZARDOUS CONDITION DETECTOR HOUSING WITH FRONT DOOR BATTERY COMPARTMENT SAFETY FEATURE

(75) Inventors: Wai Wing Malcolm Lam, Hong Kong (HK); Wing Tak Joe Choi, Chai Wan (HK)

(73) Assignee: Eyston Co., Ltd., Chai Wan (HK)

(21) Appl. No.: 13/157,624

(22) Filed: Jun. 10, 2011

(51) Int. Cl. H05K 5/00

(52) U.S. Cl. 361/679.01

(57) ABSTRACT

A life safety alarm housing for protecting a system to detect a life threatening condition and the supporting alarm electronics including a battery carrier accessible from the front of the housing. The battery carrier is configured to carry at least one battery, and the battery carrier is pivotally connected to the structure of the alarm housing to facilitate pivoting movement or rotation of the battery carrier relative to the alarm housing between a closed position and an open position. The battery carrier includes a top, bottom and two corresponding side panels. One or more of the side panels have a deformable tab extending vertically with respect to the top. The at least one tab includes one or more protuberances formed thereon projecting into the battery carrier. The housing floor includes at least one slot formed therein disposed offset from the extended edge of the deformable tab. A latch mechanism is disposed on the housing cover and is adapted to engage the battery carrier. The latch mechanism is configured to secure the battery carrier in a closed position. The tab obstructs the closure of the battery door when no battery is installed or the wrong battery is installed in the carrier.

### FIELD OF THE INVENTION

This invention relates to electronic devices that utilize a battery carrier. More particularly, the invention relates to a battery carrier for use with electronic devices, for example hazardous condition detector devices including but not limited to smoke alarms and carbon monoxide alarms, that utilize one or more batteries.

### BACKGROUND OF THE INVENTION

Electronic devices that employ battery compartments for holding one or more batteries are well known in the art. The battery compartments on such devices need to be accessible to permit insertion of one or more batteries, as well as replacement of the batteries as needed. U.S. Pat. Nos. 5,413,499 and 6,117,575 disclose pivoting battery compartments for holding 9-volt batteries that purport to facilitate battery installation into electronic devices.

In certain electronic devices it is especially important for a battery to be properly installed, and for a depleted battery to be replaced promptly by a fresh battery. An example of such a device is a smoke alarm. Many smoke alarms utilize one or more batteries, for example a single 9-volt battery, as a primary power source or as a back-up power source to power operation of the alarm in the event that main power is interrupted. If main power is interrupted, it is critical that the battery be present to ensure continued and proper operation of the alarm. Due to the important role batteries play in many smoke alarm designs, there has been a continuing effort in the industry to design smoke alarms to help ensure that a battery is properly installed in the alarm, and to provide an indication to a user when a battery is not installed or when a battery needs replacement.

One approach has been to incorporate a battery door design using a battery carrier assembly that is controlled by a complicated push-to-open/push-to-close mechanism, employing a double acting latch mechanism that includes at least one heart-shaped cam groove and at least one cam follower engaging with the cam groove. This approach is used in U.S. Pat. No. 7,492,273. However this approach has several shortcomings, as it requires a complicated and expensive molded structure, and employs a plurality of moving parts that are subject to misalignment and/or malfunction.

There is a continuing need for electronic devices, for example hazardous condition detector devices including smoke and gas alarms, that offer simplified battery installation and incorporate a simple and robust structure designed to ensure that a battery is properly installed.

### SUMMARY OF THE INVENTION

The invention relates to a structure and method for housing a battery in a hazardous condition detector device such as a smoke detector, gas detector or the like.

It is an object of the invention to provide a structure for housing a battery in a hazardous condition detector that incorporates structure to prevent the closing of the battery carrier without a battery installed.

It is another object of the invention to provide a structure for housing a battery in a hazardous condition detector that incorporates a simple easy to manufacture locking device to retain the battery in the battery carrier.

It is yet a further object of the invention to provide a housing structure for a hazardous condition detector that allows one to quickly ascertain if the hazardous condition detector has a battery installed therein.

It is still another object of the invention to provide a housing structure for a hazardous condition detector that retains the battery when opened when the detector is installed on the ceiling or with an inverted or vertical orientation on a wall.

Certain of these and other objects are satisfied by a hazardous condition detector chassis for housing a system to detect a hazardous or life threatening condition and supporting alarm electronics including a battery carrier configured to carry at least one battery, the battery carrier being pivotally connected to an alarm housing for pivoting movement relative to the alarm housing between a closed position and an open position.

The battery carrier includes a top, bottom and two corresponding side panels, at least one side panel having a deformable tab extending vertically with respect to the top, and extending below the bottom panel of the battery carrier. The at least one tab includes a protuberance formed thereon projecting into the battery carrier. The housing has a floor with at least one slot formed therein, said slot being disposed offset from the extended edge of the deformable tab. The housing also has a latch mechanism disposed on said alarm housing, the latch mechanism being adapted and configured to secure the battery carrier in a closed position.

Still other objects are satisfied, at least in part, by a life safety alarm chassis including an alarm housing that houses a system to detect a life threatening condition and alarm electronics. The housing includes a battery carrier configured to carry at least one battery. The battery carrier is pivotally connected to the alarm housing to facilitate pivoting movement of the battery carrier relative to the alarm housing between a closed position and an open position.

The battery carrier includes a top, bottom and two corresponding side panels, each side panel having a deformable tab extending vertically with respect to the top and extending below the bottom panel of the battery carrier. The tabs each having a protuberance formed thereon projecting into the battery carrier. The housing includes a floor with a pair of slots formed therein said slots being disposed offset from the extended edge of the deformable tabs. The housing also features a latch mechanism disposed thereon. The latch mechanism is configured to secure the battery carrier in a closed position.

As used herein “connected” includes physical engagement, whether direct or indirect, permanently affixed or adjustably mounted. Thus, unless specified, “connected” is intended to embrace any operationally functional connection.

As used herein “substantially,” “generally,” and other words of degree are relative modifiers intended to indicate permissible variation from the characteristic so modified. It is not intended to be limited to the absolute value or characteristic which it modifies but rather possessing more of the physical or functional characteristic than its opposite, and preferably, approaching or approximating such a physical or functional characteristic.

In the following description, reference is made to the accompanying drawing which is shown by way of illustration to the specific embodiments in which the invention may be practiced. The following illustrated embodiments are described in sufficient detail to enable those skilled in the art to practice the invention. It is to be understood that other embodiments may be utilized and that structural changes based on presently known structural and/or functional equivalents may be made without departing from the scope of the invention.

### BRIEF DESCRIPTION OF THE DRAWINGS

In order to describe the manner in which the invention can be obtained, a more particular description of the invention briefly described above will be rendered by reference to specific embodiments thereof which are illustrated in the appended drawings. Understanding that these drawings depict only typical embodiments of the invention and are not therefore to be considered to be limiting of its scope, the invention will be described and explained with additional specificity and detail through the use of the accompanying drawings.

FIG. 1 illustrates the inventive hazardous condition detector housing design with a battery installed.

FIG. 2 illustrates a close up view of the front door battery carrier of the housing design of FIG. 1.

FIG. 3 illustrates a side view of the front door battery carrier of FIG. 2 with the housing cover removed.

FIG. 4 illustrates a front view of the front door battery carrier of FIG. 2 with the housing cover removed.

FIG. 5 illustrates a view of the spring mechanism of an embodiment of the front door battery carrier of the housing design.

FIG. 6 illustrates a close up ¾ aspect view of an embodiment of the front door battery carrier with a battery installed.

FIG. 7 illustrates a close up view of the latch mechanism for the front door battery carrier of the housing design of FIG. 1.

### DETAILED DESCRIPTION OF THE EMBODIMENTS

Referring now to the figures, wherein like reference numbers denote like components, elements, or features through the various illustrated embodiments discussed in detail below, the invention is an apparatus, system and method for the housing a hazardous condition detector featuring a battery carrier for securing one or more batteries designed to be easily accessible from the front of the housing and includes various safety features to prevent the life safety device from appearing to contain batteries when it does not. While specific implementations of the disclosed technology are discussed, it should be understood that this is done for illustration purposes only. A person skilled in the relevant art will recognize that other components and configurations may be used without departing from the spirit and scope of the invention.

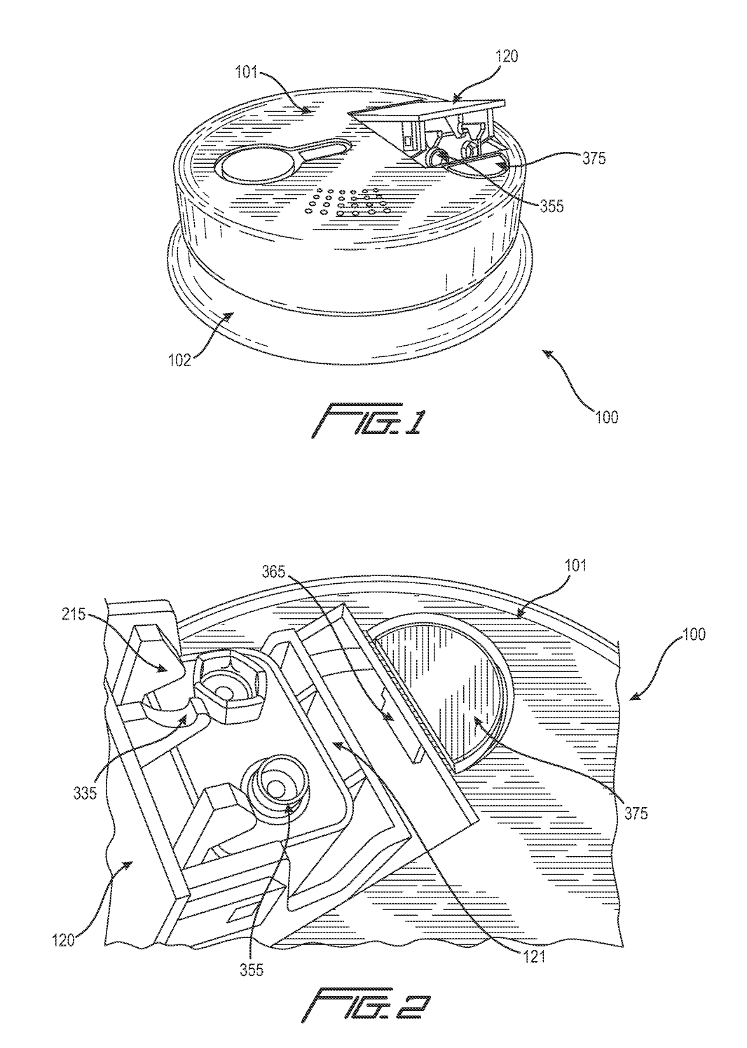

FIG. 1 shows an embodiment of the inventive hazardous condition detector housing design. The housing 100 features a hazardous condition detector chassis 102 and cover 101 for housing a system to detect hazardous or life threatening conditions and the supporting alarm electronics including a battery carrier 120 configured to carry at least one battery 355. As will become apparent through the description of the various embodiments, this novel housing design fulfills the continuing need for electronic devices, for example hazardous condition detector devices including smoke alarms and gas alarms, which feature simplified battery installation, safety features to facilitate easy confirmation that a battery is installed, and a simple and robust structure which is designed ensure that a battery when installed, is properly installed.

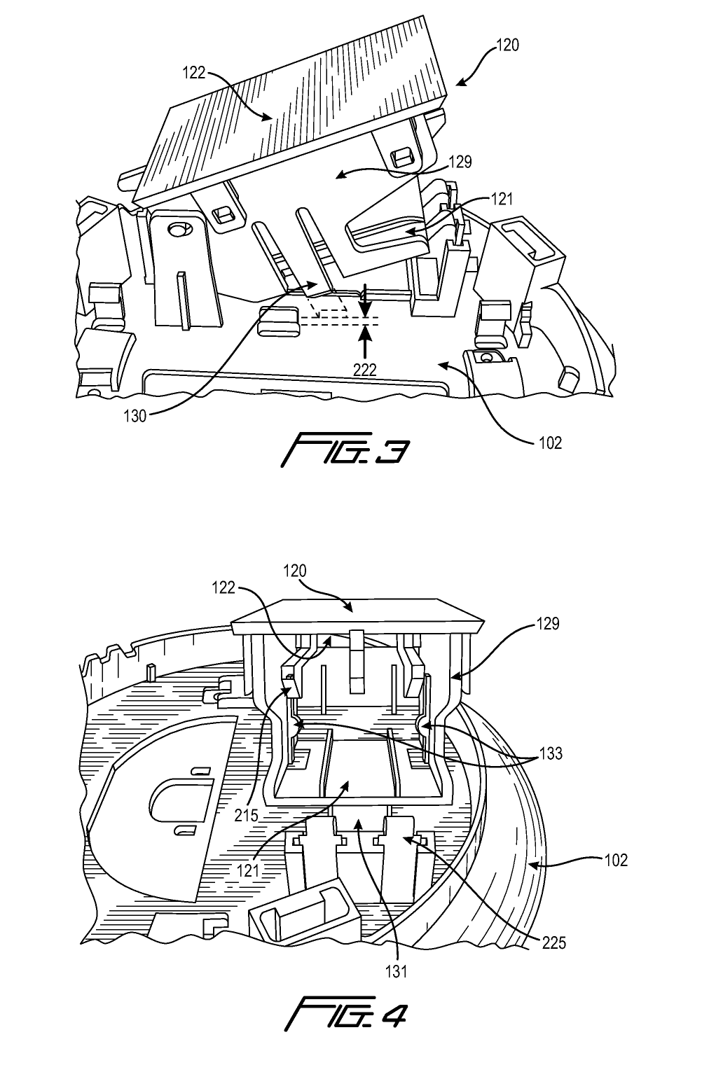

As shown in the example embodiment illustrated in FIG. 1, FIG. 2, and FIG. 3 the housing 100 includes a battery carrier 120 accessible from the front of the housing 100. The battery carrier 120 is configured to carry at least one battery 355 and is sized specifically to engage the one or more particular batteries in close registry. The battery carrier 120 of the example embodiment is sized to receive and carry a single 9 v type battery. Other embodiments may feature battery carriers that are sized to receive other types of batteries. The battery type, quantity or size is not limiting.

The battery carrier 120 is pivotally connected to the structure of the alarm housing 100 to facilitate pivoting movement or rotation of the battery carrier 120 relative to the alarm housing cover101 between a closed position and an open position. As shown in the embodiment illustrated in FIG. 3, the battery carrier 120 is attached to and pivotally coupled to the detector chassis 102. In other embodiment the battery carrier 120 may be mounted or attached directly to the housing cover 101.

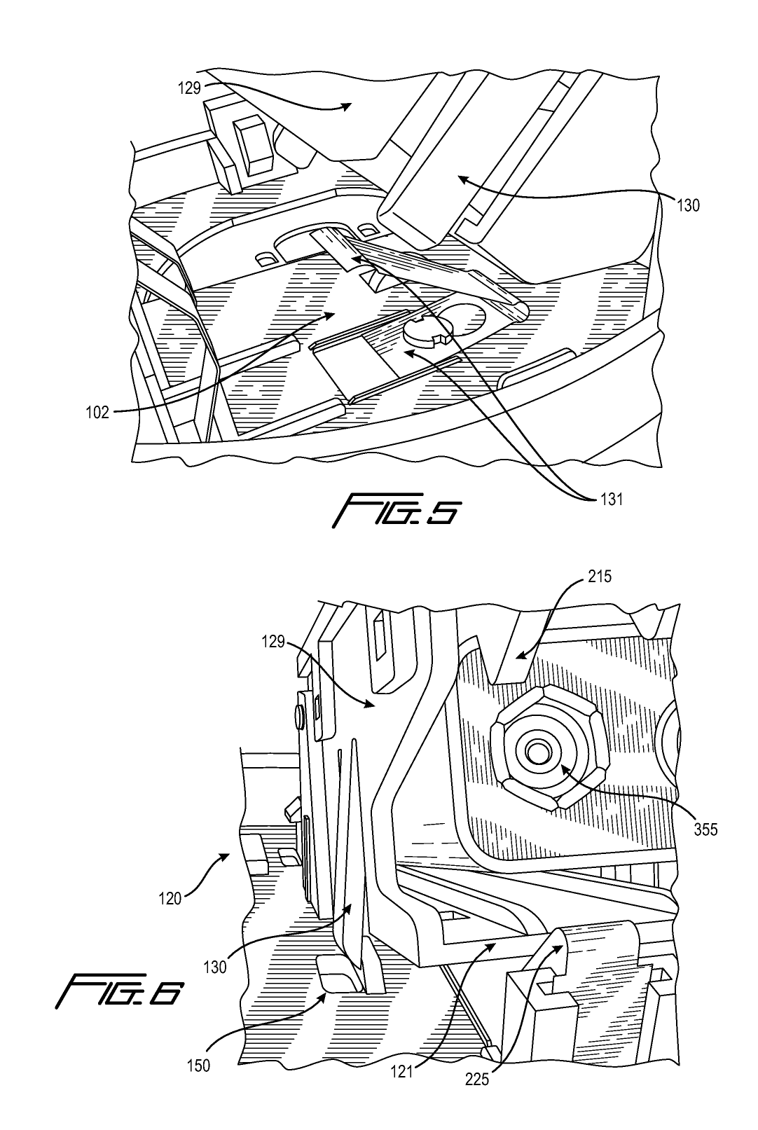

FIG. 4 illustrates yet another view of the front door battery carrier of FIG. 1, FIG. 2 and FIG. 3. As illustrated in FIG. 3 and FIG. 4, and with continued reference to FIG. 1 and FIG. 2, the battery carrier 120 includes a top 122, bottom 121 and two corresponding side panels 129. One or more of the side panels 129 have a deformable tab 130 extending vertically with respect to the top 122. The deformable tab 130 extends below the bottom panel 121 of the battery carrier 120. The deformable tab 130 includes one or more protuberances 133 formed thereon projecting into the interior portion of battery carrier 120.

The chassis or housing floor 102 includes at least one slot 150 formed therein. As shown in FIG. 3, the slot 150 is disposed with an offset 222 from the extended edge of the deformable tab 130. The offset relationship between the position of the slot 150 and the unloaded deformable tab 130 interferes with the rotation of the battery carrier 120 and effectively prevents the battery carrier 120 from being closed when no battery is installed.

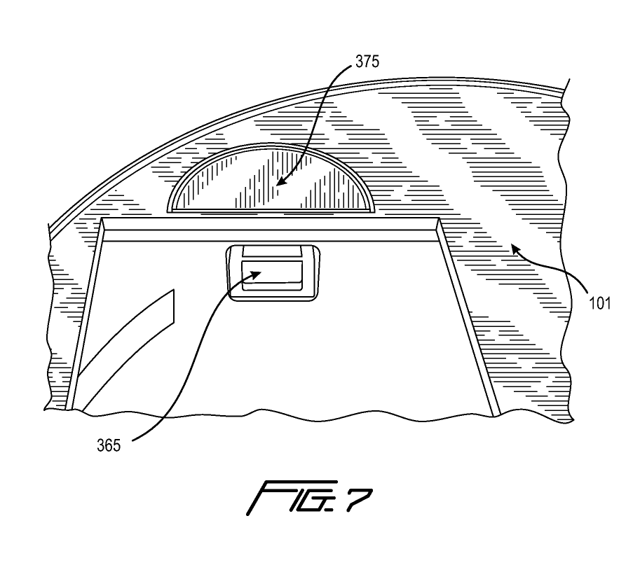

Referring now to FIGS. 6 and 7, with continued reference to FIG. 3, when a properly sized battery 355 is inserted into the battery carrier 120, the battery's case engages the protuberances 133 formed on the deformable tabs 130. This engagement of the battery 355, or specifically the battery's case, and the deformable tabs 130 through the protuberance 133 loads the deformable tabs and deforms, splays, displaces or otherwise forces the deformable tabs 130 out from the battery carrier side panels 129. The deformable tabs 130 are displaced sufficient to allow the extended edge of the deformable tabs 130 to engage or pass through the offset slots 150. The engagement of the extended edge of the deformable tab 130 and the slot 150 allow the battery carrier 120 to freely pivot or rotate relative to the alarm housing cover 101 to the closed position.

When in the closed position the battery 355 is disposed such that the battery terminals engage corresponding terminals 225 in the housing 100 and power the hazardous condition detector sensor and electronics housed therein. A latch mechanism 365 is disposed on the alarm housing 100. In the embodiment shown the latch mechanism 365 is disposed on the housing cover 101 and is adapted to engage the battery carrier 120 via a battery carrier latch or locking tab 335, however the latch mechanism 365 may be disposed anywhere on the housing 100 that allows the latch mechanism 365 to engage the battery carrier 120 and secure the battery carrier 120 in a closed position.

In the embodiment shown in FIGS. 1, 2 and 7 the latch mechanism 365 includes a latch button 375 disposed on the housing cover 122 to actuate the mechanism and release the latch's engagement of the battery carrier latch tab 335. The latch tab 335 is disposed on the top panel 122 of the battery carrier 120, and is latch tab is adapted to disengage the alarm housing latch mechanism 365 when the latch button 375 is pushed allowing the battery carrier 120 to rotate to an open position and expose the battery 355 for removal or replacement.

Other embodiments may include a latch mechanism 365 that does have a physical button. For example pushing a battery carrier housing in a particular corner may be sufficient to engage the latch mechanism.

The battery carrier 120 connected to the alarm housing 100 also features a deformable flange 215 disposed on the interior surface 122 of the top panel of the battery carrier 120. This deformable flange 215 is deformed and displaced by the battery 355 when the proper sized battery 355 is inserted into the battery carrier 120. When the battery 355 is fully inserted the flange 215 returns to it the original shape and seats a battery 355 into the battery carrier 120. The positive engagement of the battery 355 with the battery carrier flange 215 retains the battery 355 preventing it from being unintentionally removed or otherwise falling out of the battery carrier 120 when the latch is mechanism is pressed.

The alarm housing 100 also includes a spring 131 disposed between the battery carrier 120 and the alarm housing floor 102, engaging the bottom panel 121 of the battery carrier 120 and the alarm housing floor 102. The spring 131 is preferably in a compression state when the battery carrier 120 is closed. When the latch mechanism 365 is released the compression forces on the spring are released and cause battery carrier 120 to rotate out and expose the battery carrier for battery removal or replacement. In other embodiments the springs may be in the form of a deformable, or resilient piece of plastic or other resilient or semi resilient material.

Although specific example embodiments have been illustrated and described herein, those of ordinary skill in the art appreciate that other variations, aspects, or embodiments may be contemplated, and/or practiced without departing from the scope or the spirit of the appended claims, for example the disclosed apparatus may be employed to provide efficient and easy battery access for a burglar alarm or a combination hazardous condition detector and safety light.

1. A life safety alarm housing for a system to detect a life threatening condition and supporting alarm electronics comprising;
a battery carrier configured to carry at least one battery, said battery carrier being pivotally connected to an alarm housing for pivoting movement of the battery carrier relative to the alarm housing between a closed position and an open position;
said battery carrier having a top, bottom and two corresponding side panels, at least one side panel having a deformable tab extending vertically with respect to the top and extending below the bottom panel of the battery carrier, said at least one tab having a protuberance formed thereon projecting into the battery carrier;
said housing having a floor with at least one slot formed therein said slot being disposed offset from the extended edge of the deformable tab;
a latch mechanism disposed on said alarm housing, the latch mechanism configured to secure the battery carrier in a closed position.

2. The life safety alarm housing of claim 1 wherein said battery carrier connected to said alarm housing further comprises a deformable flange disposed on the interior surface of the top panel of said battery carrier to engage and seat a battery inserted into said battery carrier.

3. The life safety alarm housing of claim 1 further comprising a spring, said spring being disposed between said battery carrier and said alarm housing floor, engaging said bottom panel of said battery carrier and said alarm housing floor said spring being in a compression state when said battery carrier is closed.

4. The life safety alarm housing of claim 2 wherein said battery carrier tab, when engaged by a battery inserted into the battery carrier is deformed by the battery, and aligns with the corresponding pair of slot formed in the alarm housing floor.

5. The life safety alarm housing of claim 2 wherein said battery carrier connected to said alarm housing further comprises a locking tab disposed on the top panel of the battery carrier, said locking tab being configured to disengage the alarm housing latch mechanism when pushed and allow to battery carrier to rotate to an open position.

6. The life safety alarm of claim 2 wherein said tab obstructs the closure of the battery door when no battery is installed in the carrier.

7. A life safety alarm housing, comprising:
an alarm housing for a system to detect a life threatening condition and alarm electronics;
a battery carrier configured to carry at least one battery, the battery carrier is pivotally connected to the alarm housing for pivoting movement relative to the alarm housing between a closed position and an open position;
said battery carrier having a top, bottom and two corresponding side panels, each side panel having a deformable tab extending vertically with respect to the top and extending below the bottom panel of the battery carrier, said tabs each having a protuberance formed thereon projecting into the battery carrier;
said housing having a floor with a pair of slots formed therein said slots being disposed offset from the extended edge of the deformable tabs; and,
a latch mechanism disposed on said alarm housing, the latch mechanism configured to secure the battery carrier in a closed position.

8. The life safety alarm housing of claim 7 wherein said battery carrier connected to said alarm housing further comprises a deformable flange disposed on the interior surface of the top panel of said battery carrier to engage and seat a battery inserted into said battery carrier.

9. The life safety alarm housing of claim 8 further comprising a spring, said spring being disposed between said battery carrier and said alarm housing, engaging said bottom panel of said battery carrier and said alarm housing said spring being in a compression state when said battery carrier is closed.

10. The life safety alarm housing of claim 8 wherein said battery carrier tabs, when engaged by a battery inserted into the battery carrier and deform by the battery, align with the corresponding pair of slots formed in the alarm housing floor.

11. The life safety alarm housing of claim 8 wherein said battery carrier connected to said alarm housing further comprises a locking tab disposed on the top panel of the battery carrier, said locking tab being configured to disengage the alarm housing latch mechanism when pushed and allow to battery carrier to rotate to an open position.

12. The life safety alarm housing of claim 8 wherein said tabs obstruct the closure of the battery door when no battery is installed in the carrier.

13. A life safety alarm, comprising:
an alarm housing that houses a system to detect a life threatening condition and alarm electronics;
a battery carrier configured to carry at least one battery, the battery carrier is pivotally connected to the alarm housing for pivoting movement relative to the alarm housing between a closed position and an open position;
said battery carrier having a top, bottom and two corresponding side panels, each side panel having a deformable tab extending vertically with respect to the top and extending below the bottom panel of the battery carrier, said tabs each having a protuberance formed thereon projecting into the battery carrier;
said housing having a floor with a pair of slots formed therein said slots being disposed offset from the extended edge of the deformable tabs; and,
a latch mechanism disposed on said alarm housing, the latch mechanism configured to secure the battery carrier in a closed position.
